(19) United States
(12) Patent Application Publication
(10) Pub. No.: US 2019/0305024 A1
(43) Pub. Date: Oct. 3, 2019

(54) CHIP PACKAGING DEVICE AND METHOD OF MAKING THE SAME

(71) Applicant: Tong Hsing Electronic Industries, Ltd., Taipei City (TW)

(72) Inventors: Zzu-Chi CHIU, Taipei City (TW); Shao-Pin RU, Taipei City (TW); Tsung-Pin HSIEH, Taipei City (TW); Chien-Cheng WEI, Taipei City (TW)

(21) Appl. No.: 16/363,760

(22) Filed: Mar. 25, 2019

(30) Foreign Application Priority Data
Mar. 28, 2018 (TW) 107110644

(51) Int. Cl. H01L 27/146

(52) U.S. Cl. CPC H01L 27/14618; H01L 27/14683; H01L 27/14636

(57) ABSTRACT

A chip packaging device includes a chip carrier, a chip and a packaging structure that includes a packaging plate and a connecting unit. The chip carrier includes a substrate and the chip is disposed thereon. The packaging plate and the substrate are respectively disposed at two opposite sides of the chip. The connecting unit has first and a second ends, which are respectively connected to the packaging plate and the chip. The first and second ends respectively have first and second cross-sectional areas perpendicular to an axis, and the second cross-sectional area is smaller than the first cross-sectional area.

### CROSS-REFERENCE TO RELATED APPLICATION

This application claims priority of Taiwanese Invention Patent Application No. 107110644, filed on Mar. 28, 2018.

### FIELD

The disclosure relates to a chip packaging device, and more particularly to a chip packaging device and a method of making the same.

### BACKGROUND

Semiconductor packaging structure is used for accommodating and covering one or more semiconductor components. For example, after a die is cut from a wafer, the die is packaged in a semiconductor packaging structure, which can prevent the die from being damaged or malfunctioned due to external force or moisture, thus offering protection to the die during assembly and shipping.

Image sensors use image chips to generate image data, which are commonly used in digital cameras (DC), or other electronic products having imaging functions, such as mobile phones, tablet computers, and the like. Currently, the image chips commonly used in the image sensors are mainly complementary metal-oxide semiconductor (CMOS) chips, which not only have low production cost, but also have an advantage of being small in size, and thus are widely developed and manufactured. For miniaturization of the image sensor, in addition to the type of the image chip, the packaging structure used to package the image chip is also important.

Therefore, there is a need in the art to develop a chip packaging device that has a miniaturized structure and exhibits a desired chip-protection function.

### SUMMARY

Therefore, an object of the disclosure is to provide a chip packaging device and a method of making the same that can alleviate at least one of the drawbacks of the prior art.

According to one aspect of the disclosure, a chip packaging device includes a chip carrier, a chip and a packaging structure. The chip carrier includes a substrate and an electrically conductive unit disposed on the substrate. The chip is disposed on the substrate and electrically connected to the electrically conductive unit. The packaging structure includes a packaging plate spaced apart from the chip and a connecting unit. The packaging plate and the substrate are respectively disposed at two opposite sides of the chip. The connecting unit has first and second ends which are opposite along an axis and which are respectively connected to the packaging plate and the chip. The first and second ends of the connecting unit respectively have first and second cross-sectional areas perpendicular to the axis, and the second cross-sectional area is smaller than the first cross-sectional area.

According to another aspect of the disclosure, a method for making a chip packaging device includes the steps of:

(a)providing a chip carrier, a chip, a packaging plate and a connecting unit connected to the packaging plate, the chip carrier including a substrate and an electrically conductive unit disposed on the substrate,

(b)disposing the chip on the substrate and electrically connecting the chip to the electrically conductive unit; and

(c)connecting the packaging plate and the chip through the connecting unit in such a manner that the packaging plate is spaced apart from the chip.

The connecting unit has a first end connected to the packaging plate, and a second end connected to the chip and disposed opposite to the first end along an axis. The first and second ends respectively have first and second cross-sectional areas perpendicular to the axis, and the second cross-sectional area is smaller than the first cross-sectional area.

### BRIEF DESCRIPTION OF THE DRAWINGS

Other features and advantages of the disclosure will become apparent in the following detailed description of the embodiment (s) with reference to the accompanying drawings, of which:

FIG. 1 is a schematic view showing an embodiment of a chip packaging device according to the present disclosure;

FIG. 2 is a flow chart illustrating consecutive steps of a method of making the embodiment of the chip packaging device;

FIGS. 3 to 9 are schematic views respectively showing the consecutive steps of the method shown in FIG. 2;

FIG. 10 is a schematic view similar to FIG. 6, showing a variation of the method shown in FIG. 2, in which an adhesive layer is formed on a second connecting layer of a connecting unit;

FIG. 11 is an exploded schematic view similar to FIG. 8, showing one of the consecutive steps of the variation of the method, in which a packaging structure is connected to a chip through the connecting unit;

FIG. 12 is a schematic view similar to FIG. 6, showing another variation of the method shown in FIG. 2, in which a first connecting layer and a second connecting layer of the connecting unit are integrally formed into a single layer structure; and

FIG. 13 is a schematic view similar to FIG. 1, showing a variation of the embodiment of the chip packaging device according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

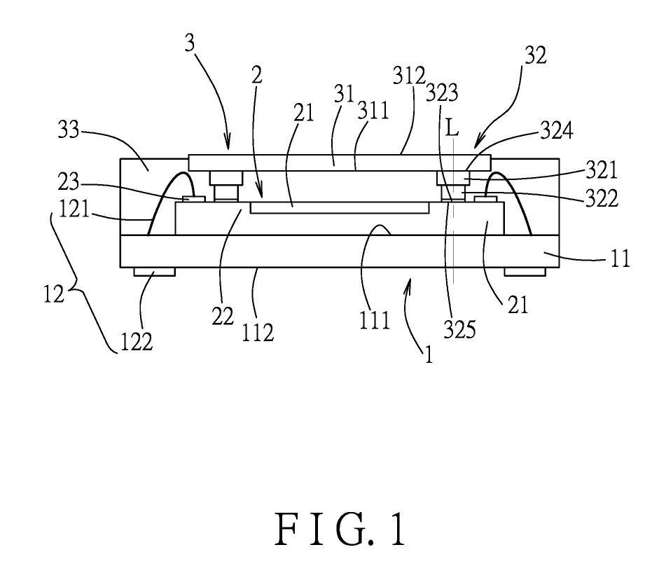

Referring to FIG. 1, an embodiment of a chip packaging device of this disclosure includes a chip carrier 1, a chip 2 and a packaging structure 3. The chip carrier 1 includes a substrate 11 and an electrically conductive unit 12 disposed on the substrate 11. The substrate 11 is used to support the chip 2 and includes an inner surface 111 and an outer surface 112 opposite to the inner surface 111 along an axis (L). In this embodiment, the substrate 11 is formed into a rectangular sheet and is made of a ceramic material having high thermal conductivity or a resin material. Examples of the ceramic material may include, but are not limited to, aluminium oxide, aluminium nitride, and the combination thereof. In certain embodiments, the substrate 11 may be made of copper, iron, fiberglass, or other materials. The electrically conductive unit 12 includes a plurality of wires 121 disposed on the inner surface 111 of the substrate 11 and a plurality of electrically conductive layers 122 disposed on the outer surface 112 of the substrate 11. The electrically conductive unit 12 may includes other circuit wires (not shown in the figures) disposed on or in the substrate 11. The wires 121 may be made of a metal-based material. Examples of the metal-based material may include, but are not limited to, gold, copper, silver, copper-palladium alloy, and combinations thereof. The electrically conductive unit 12 provides transmission of electrical signal between the chip 2 and an external circuit board (not shown in the figures).

The chip 2 is disposed on the substrate 11 and is electrically connected to the electrically conductive unit 12. In this embodiment, the chip 2 is an image sensor chip that includes a photosensitive portion 21, a surrounding portion 22 surrounding the photosensitive portion 21, and bonding pads 23 which are adjacent to the photosensitive portion 21, disposed on the surrounding portion 22, and electrically connected to the electrically conductive unit 12. To be specific, the bonding pads 23 are respectively electrically connected to the wires 121 so that the chip is electrically connected to the electrically conductive unit 12 through wire bonding. It should be noted that the type of the chip 2 and the way for electrically connecting the chip 2 with the electrically conductive unit 12 are not limited to those mentioned in this embodiment.

The packaging structure 3 includes a packaging plate 31 and a connecting unit 32. The packaging plate 31 and the substrate 11 are respectively disposed at two opposite sides of the chip 2. The packaging plate 31 is spaced apart from the chip 2 by the connecting unit 32. The packaging plate 31 has a first surface 311 facing the substrate 11 and the photosensitive portion 21 of the chip 2, and a second surface 312 opposite to the first surface 311. In this embodiment, the packaging plate 31 is transparent and is made of a light transmissive material, such as glass. Therefore, the chip 2, which is an image sensor chip, may receive external light that is transmitted through the packaging plate 31 so as to generate corresponding image signals. However, in certain embodiments, in which the chip 2 is a non-image sensor chip, the material of the packaging plate 31 is not limited to the light transmissive material.

In this embodiment, the connecting unit 32 surrounds the photosensitive portion 21 of the chip 2 and has first and second ends 324, 325 which are opposite along the axis (L) and which are respectively connected to the packaging plate 31 and the surrounding portion 22 of the chip 2. The first end 324 of the connecting unit 32 has a first cross-sectional area perpendicular to the axis (L), the second end 325 of the connecting unit 32 has a second cross-sectional are perpendicular to the axis (L), and the second cross-sectional is smaller than the first cross-sectional area. In this embodiment, the second end 325 of the connecting unit 32 is disposed on the surrounding portion 22 between the photosensitive portion 21 and the bonding pads 23. However, the connecting unit 32 is not limited to be disposed between the photosensitive portion 21 and the bonding pads 23, as long as the connecting unit 32 is disposed on the surrounding portion 22. In this embodiment, the connecting unit 32 includes a first connecting layer 321 connected to the first surface 311 and has the first end 324, a second connecting layer 322 connected to the first connecting layer 321 oppositely of the packaging plate 31, and an adhesive layer 323 that bonds the second connecting layer 322 to the chip 2 and that has the second end 325. Each of the first connecting layer 321, the second connecting layer 322 and the adhesive layer 323 has cross-sectional area perpendicular to the axis (L). In this embodiment, the cross-sectional area of the adhesive layer 323 is equal to or smaller than the cross-sectional area of the second connecting layer 322, and the cross-sectional area of the second connecting layer 322 is smaller than the cross-sectional area of the first connecting layer 321. In certain embodiments, the connecting unit 32 is tapered from the first end 324 to the second end 325. In certain embodiments, the first connecting layer 321 has a width of 100 μm and a thickness of 50 μm, and the second connecting layer 322 has a width of 50 urn and a thickness of 50 μm. The first and second connecting layers 321, 322 may be made of any photosensitive material. The adhesive layer 323 is made of a photosensitive adhesive (such as UV curing adhesive) which exhibits fast-curing property, and may have a high coefficient of viscosity and not be easily diffusible or flowable during the process of making the chip packaging device. As such, the size of the adhesive layer 323 can be adjusted so as to control the size of the connecting unit 32, thereby contributing to the miniaturization of the chip packaging device. Moreover, since the photosensitive adhesive of the adhesive layer 323 has a fast-curing property, the adhesive layer 323 and the chip 2 can be prevented from being delaminated or deformed during the adhesion procedure. Meanwhile, since the photosensitive portion 21 of the chip 2 is surrounded by the connecting unit 32, the external water, moisture or gas may be prevented from penetrating into the photosensitive portion 21 so as to reduce possible damage to the photosensitive portion 21.

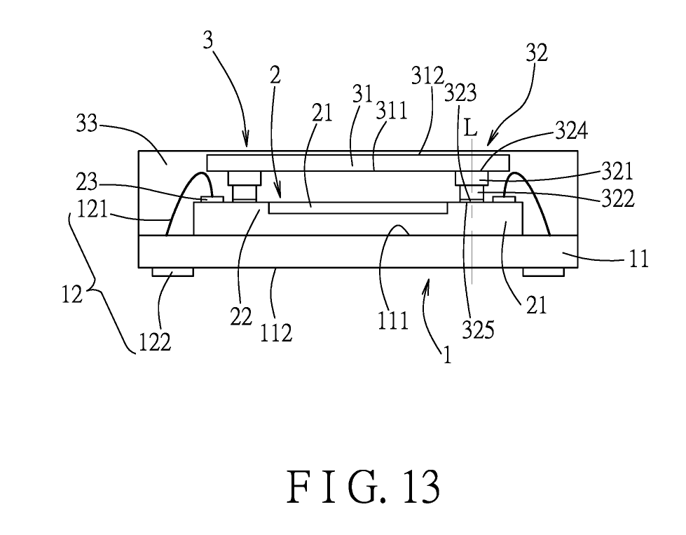

Referring again to FIG. 1, the packaging structure 3 further includes an encapsulant 33 that covers the chip 2 and that cooperates with the substrate 11, the connecting unit 32 and the packaging plate 31 to enclose the chip 2 thereamong, so as to ensure safety of electrical signal transmission and to further prevent water, moisture or gas from penetrating into the chip 2. In this embodiment, the space between the photosensitive portion 21 and the packaging plate 31 is not filled with the encapsulant 33, and the second surface 312 of the packaging plate 31 is not covered by the encapsulant 33. Thus, external light may pass through the second surface 312 of the packaging plate 31 and arrives at the photosensitive portion 21 of the chip 2 without undesired influence by the encapsulant 33. In this embodiment, except for the electrically conductive layers 122, the electrically conductive unit 12 is enclosed by the encapsulant 33 to ensure electrical safety. In this embodiment, the encapsulant 33 is made of a material that does not affect the properties of the chip 2 when the material is being cured. Examples of the material suitable for making the encapsulant 33 may include, but are not limited to, epoxy resin, polyamine, a silicon-based material, an oxide-based material and combinations thereof. In a variation of the embodiment of the chip packaging device, as shown in FIG. 13, the encapsulant 33 covers the chip 2, the packaging plate 31 and the connecting unit 32.

It should be noted that, the design of the connecting unit 32 is not limited to the aforesaid and may be adjusted according to actual requirements. For example, the connecting unit 32 may include additional connecting layer (s) in addition to the first connecting layer 321 and the second connecting layer 322, or the first connecting layer 321 and the second connecting layer 322 may be integrally formed into a single layer structure that has a change in the cross-sectional areas along the axis (L).

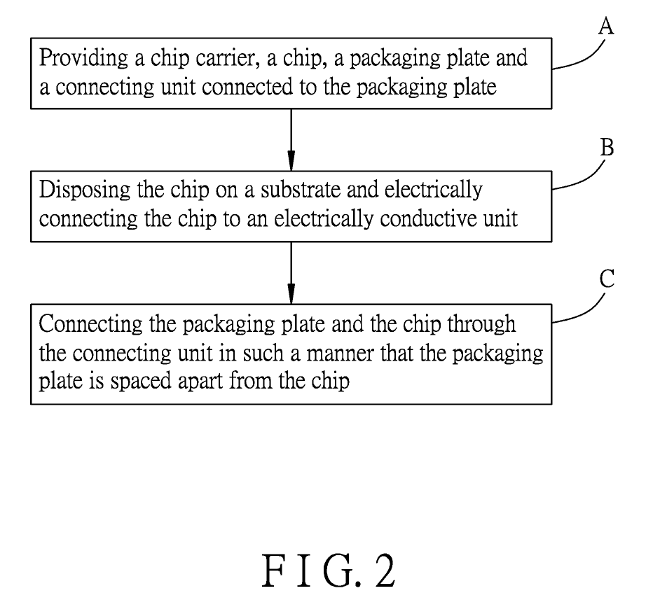

According to this disclosure, a method for making the embodiment of the chip packaging device of this disclosure includes the following Steps A to C (see FIG. 2).

In Step A, the chip carrier 1, the chip 2, the packaging plate 31 and the connecting unit 32 connected to the packaging plate 31 is provided. The chip carrier includes the substrate 11 and the electrically conductive unit 12 disposed on the substrate 11.

In Step B, the chip 2 is disposed on the substrate 11 and the chip 2 is electrically connected to the electrically conductive unit 12.

In Step C, the packaging plate 31 and the chip 2 are connected through the connecting unit 32 in such a manner that the packaging plate 31 is spaced apart from the chip 2.

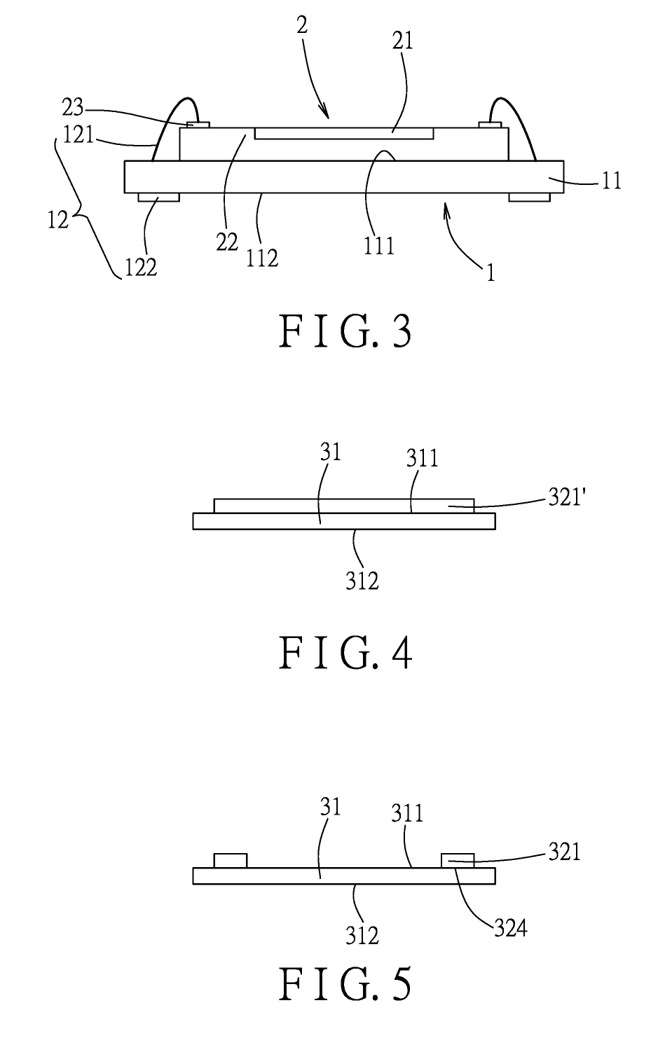

Specifically, in step (B), the chip 2 is disposed on the substrate 11 with the photosensitive portion 21 facing upward, and the bonding pads 23 of the chip 2 and the wires 121 of the electrically conductive unit 12 are electrically connected with each other (see FIG. 3).

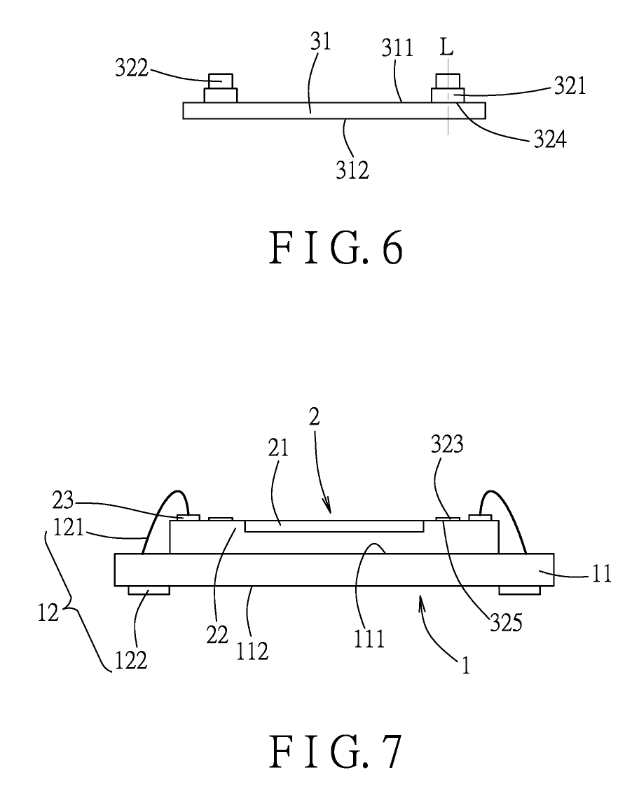

The packaging plate 31 has the first surface 311 on which the connecting unit 32 is disposed and the second surface 312 opposite to the first surface 311. The connecting unit 32 includes the first connecting layer 321 disposed on the first surface 311 and having the first end 324, and the second connecting layer 322 connected to the first connecting layer 321. The first connecting layer 321 is formed by applying a first photosensitive material layer 321′ on the first surface 311 of the packaging plate 31, followed by patterning the first photosensitive material layer 321′ into the first connecting layer 321 by photolithography (see FIGS. 4 and 5). The first photosensitive material layer 321′ may be applied in a liquid form or being laminated onto the packaging plate 31 in a film or sheet form. The second connecting layer 322 is formed by applying a second photosensitive material layer on the first connecting layer 321, followed by patterning the second photosensitive material layer into the second connecting layer 322 by photolithography. Each of the first and second connecting layers 321, 322 has a cross-sectional area perpendicular to the axis (L) and the cross-sectional area of the second connecting layer 322 is smaller than the cross-sectional area of the first connecting layer 321 (see FIG. 6). The connecting unit 32 further includes the adhesive layer 323 that has the second end 325 of the connecting unit 32. In this embodiment, in Step A, the adhesive layer 323 is formed on the chip 2. Specifically, the adhesive layer 323 is dispensed onto the surrounding portion 22 of the chip 2 and is positioned between the photosensitive portion 21 and the bonding pads 23 (see FIG. 7).

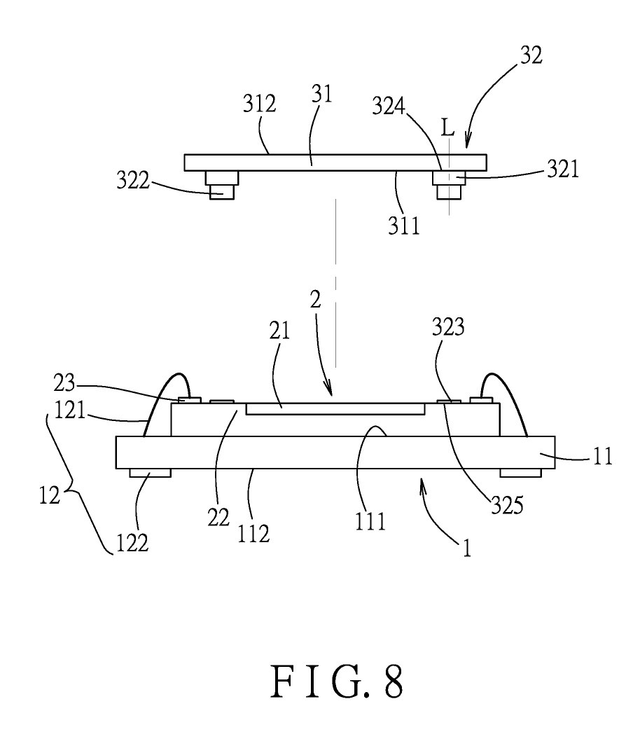

As shown in FIG. 8, before the packaging plate 31 is connected to the chip 2, the first surface 311 of the packaging plate 31 is faced downward with the packaging plate 31 accurately disposed on the chip 2 in such manner that the second connecting layer 322 is accurately aligned with the corresponding adhesive layer 323 that is formed on the chip 2. In Step C, the packaging plate 31 and the chip 2 are connected through bonding the second connecting layer 322 to the adhesive layer 323.

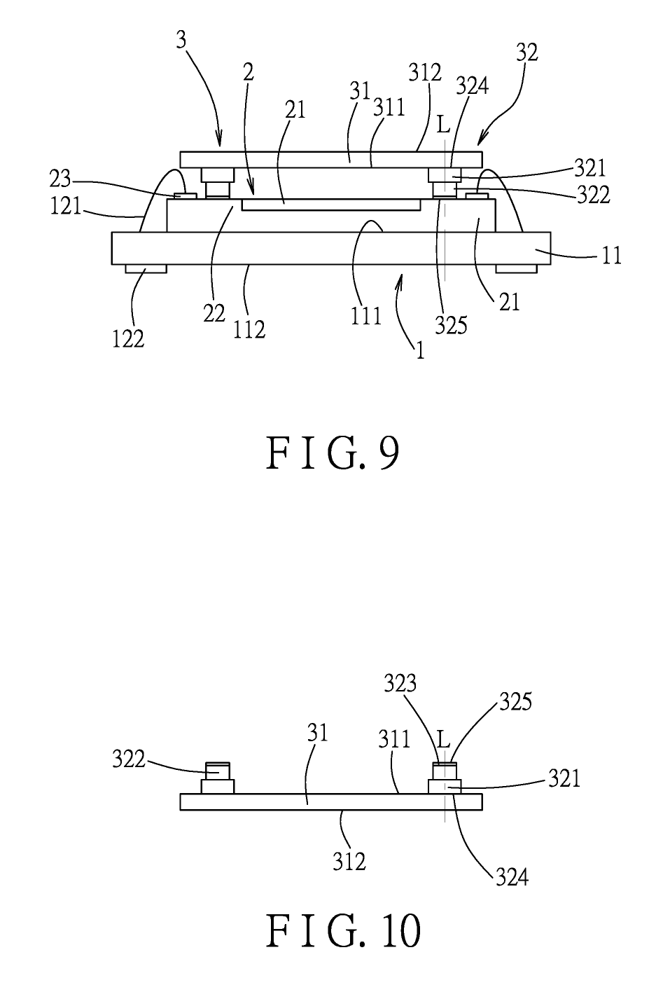

As shown in FIG. 9, the connecting unit 32 has the first end 324 of the first connecting layer 321 connected to the packaging plate 31, and the second end 325 of the adhesive layer 323 disposed opposite to the first end 324 along the axis (L) connected to the chip 2. As such, the packaging plate 31 is spaced apart from the chip 2 by the connecting unit 32. The first end 324 has a first cross-sectional area perpendicular to the axis (L), the second end 325 has a second cross-sectional area perpendicular to the axis (L), and the second cross-sectional area is smaller than the first cross-sectional area.

The method for making the embodiment of the chip packaging device further includes, after Step C, a Step D of applying the encapsulant 33 on the substrate to cover the chip 2 and the connecting unit 32, so that the encapsulant 33 cooperates with the substrate 11, the connecting unit 32 and the packaging plate 31 to enclose the chip 2 thereamong, thereby completing the fabrication of the embodiment of the chip packaging device.

It should be noted that, the method for making the variation of the embodiment of the chip packaging device shown in FIG. 13 is similar to the aforesaid method except that, in Step D, the chip 2, the packaging plate 31 and the connecting unit 32 are covered with the encapsulant 33 (i.e., the packaging plate 31 is enclosed by the encapsulant 33 without exposing the second surface 312).

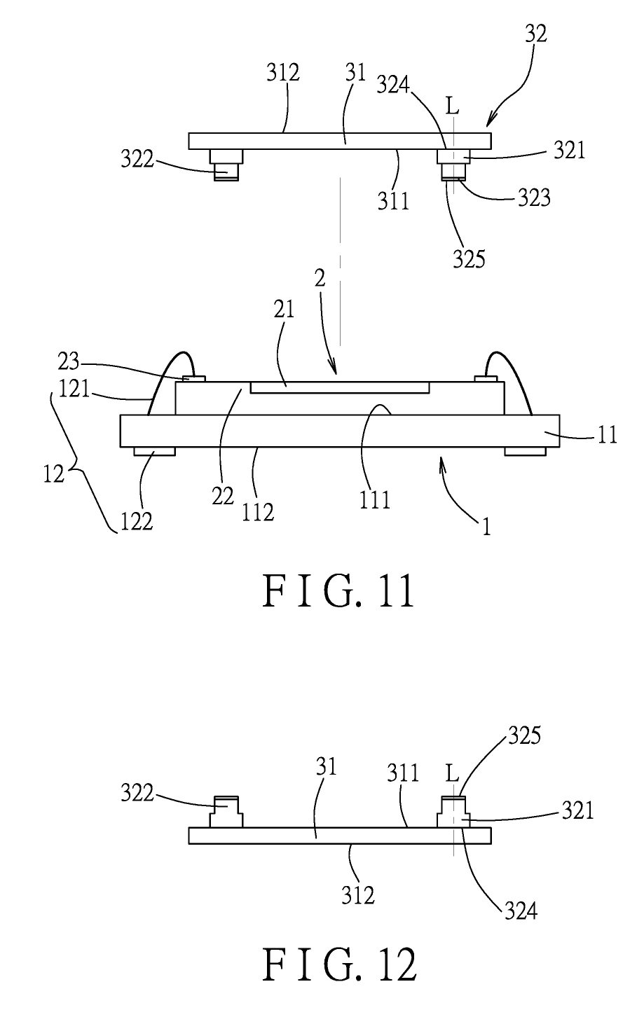

FIGS. 10 and 11 show a variation of the aforesaid method for making the embodiment of the chip packaging device of this disclosure. In this variation of the method, the adhesive layer 323 in Step A is formed on the second connecting layer 322, and in Step C, the packaging structure 3 and the chip 2 are connected with each other through bonding the adhesive layer 323 to the chip 2.

Specifically, after the first connecting layer 321 and the second connecting layer 322 are sequentially formed on the packaging plate 31, the adhesive layer 323 is formed by stamping the adhesive (such as UV curing adhesive) onto the second connecting layer 322. As shown in FIG. 11, before the packaging structure 3 is connected to the chip 2, the first surface 311 of the packaging plate 31 is faced downward with the packaging structure 3 accurately aligned with the chip 2. In Step C, the packaging structure 3 and the chip 2 are connected through bonding the adhesive layer 323 formed on the second connecting layer 322 to the chip 2.

It should be noted that, as mentioned above, the first connecting layer 321 and the second connecting layer 322 may be integrally formed into a single layer structure that has a change in the cross-sectional areas along the axis (L) (see FIG. 12) The integral single layer structure may be obtained by thereto-compression bonding of the first and second connecting layers 321, 322. Other methods which can accomplish the integral single layer structure may also be used in this disclosure. The integral single layer structure would make the connecting unit 32 more dense and seamless so as to further prevent water, moisture or gas from penetrating into the chip 2. After the integral single layer structure is obtained, the adhesive layer 323 is formed on the second connecting layer 322, and then the packaging structure 3 and the chip 2 are connected through bonding the adhesive layer 323 to the chip 2.

In summary, by virtue of the connecting unit 32 having the second cross-sectional area of the second end 325 being smaller than the first cross-sectional area of the first end 324, the chip packaging device of this disclosure maybe miniaturized. Moreover, when the adhesive layer 323 is a photosensitive adhesive, the fast-curing property of the photosensitive adhesive may enhance the interconnection between the chip 2 and the connecting unit 32, thereby preventing penetration of water, moisture and gas from external environment into the chip packaging device so as to protect the chip 2 from possible damage.

In the description above, for the purposes of explanation, numerous specific details have been set forth in order to provide a thorough understanding of the embodiment(s). It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A chip packaging device, comprising:
a chip carrier that includes a substrate and an electrically conductive unit disposed on said substrate;
a chip that is disposed on said substrate and electrically connected to said electrically conductive unit; and
a packaging structure that includes a packaging plate spaced apart from said chip and a connecting unit, said packaging plate and said substrate are respectively disposed at two opposite sides of said chip, said connecting unit having first and second ends which are opposite along an axis and which are respectively connected to said packaging plate and said chip,
wherein said first end of said connecting unit has a first cross-sectional area perpendicular to said axis, said second end of said connecting unit having a second cross-sectional area perpendicular to said axis, said second cross-sectional area being smaller than said first cross-sectional area.

2. The chip packaging device as claimed in claim 1, wherein said chip is an image sensor chip that includes a photosensitive portion facing said packaging plate and a bonding pad adjacent to said photosensitive portion and electrically connected to said electrically conductive unit, said second end of said connecting unit being disposed between said photosensitive portion and said bonding pad.

3. The chip packaging device as claimed in claim 1, wherein said connecting unit is tapered from said first end to said second end.

4. The chip packaging device as claimed in claim 1, wherein said packaging plate has a first surface facing said chip and a second surface opposite to said first surface, said connecting unit including a first connecting layer connected to said first surface and having said first end, and a second connecting layer connected to said first connecting layer oppositely of said packaging plate, each of said first and second connecting layers having a cross-sectional area perpendicular to said axis, the cross-sectional area of said second connecting layer being smaller than the cross-sectional area of said first connecting layer.

5. The chip packaging device as claimed in claim 4, wherein said connecting unit further includes an adhesive layer that bonds said second connecting layer to said chip and that has said second end.

6. The chip packaging device as claimed in claim 5, wherein said adhesive layer is a photosensitive adhesive.

7. The chip packaging device as claimed in claim 1, wherein said packaging structure further includes an encapsulant that covers said chip and that cooperates with said substrate, said connecting unit and said packaging plate to enclose said chip thereamong.

8. The chip packaging device as claimed in claim 1, wherein said packaging structure further includes an encapsulant that covers said chip, said packaging plate and said connecting unit.

9. A method for making a chip packaging device, comprising the steps of:
(A) providing a chip carrier, a chip, a packaging plate and a connecting unit connected to the packaging plate, the chip carrier including a substrate and an electrically conductive unit disposed on the substrate,
(B) disposing the chip on the substrate and electrically connecting the chip to the electrically conductive unit; and
(C)connecting the packaging plate and the chip through the connecting unit in such a manner that the packaging plate is spaced apart from the chip;
wherein the connecting unit having a first end connected to the packaging plate, and a second end connected to the chip and disposed opposite to the first end along an axis, the first end having a first cross-sectional area perpendicular to the axis, the second end having a second cross-sectional area perpendicular to the axis, the second cross-sectional area being smaller than the first cross-sectional area.

10. The method as claimed in claim 9, wherein, in step (A), the packaging plate includes a first surface on which the connecting unit is disposed and a second surface opposite to the first surface, the connecting unit includes a first connecting layer disposed on the first surface and having the first end, and a second connecting layer connected to the first connecting layer, each of the first and second connecting layers having a cross-sectional area perpendicular to the axis, the cross-sectional area of the second connecting layer being smaller than the cross-sectional area of the first connecting layer.

11. The method as claimed in claim 10, wherein
the first connecting layer is formed by applying a first photosensitive material layer on the first surface of the packaging plate, followed by patterning the first photosensitive material layer into the first connecting layer by photolithography, and
the second connecting layer is formed by applying a second photosensitive material layer on the first connecting layer, followed by patterning the second photosensitive material layer into the second connecting layer by photolithography.

12. The method as claimed in claim 10, wherein the first connecting layer and the second connecting layer are integrally formed into a single layer structure by thermo-compression bonding.

13. The method as claimed in claim 10, wherein the connecting unit further includes an adhesive layer that has the second end of the connecting unit,
in step (A), the adhesive layer is formed on the chip, and
in step (C), the packaging plate and the chip are connected through bonding the second connecting layer to the adhesive layer.

14. The method as claimed in claim 13, wherein the adhesive layer is a photosensitive adhesive.

15. The method as claimed in claim 10, wherein the connecting unit further includes an adhesive layer that has the second end of the connecting unit,
in step (A), the adhesive layer is formed on the second connecting layer, and
in step (C), the packaging structure and the chip are connected through bonding the adhesive layer to the chip.

16. The method as claimed in claim 9, further comprising, after step (C), a step (D) of applying an encapsulant on the substrate so that the encapsulant cooperates with the substrate, the connecting unit and the packaging plate to enclose the chip thereamong.

17. The method as claimed in claim 9, further comprising, after step (C), a step (D) of covering the chip, the packaging plate and the connecting unit with an encapsulant.
